(19) United States
(12) Patent Application Publication
(10) Pub. No.: US 2025/0329643 A1
(43) Pub. Date: Oct. 23, 2025

(54) SEMICONDUCTOR INTERCONNECT STRUCTURE AND METHOD FOR MANUFACTURING THE SAME

(71) Applicant: United Microelectronics Corp., Hsinchu (TW)

(72) Inventors: Shin-Hung LI, Nantou County (TW); Shan-Shi Huang, Hsinchu City (TW)

(21) Appl. No.: 18/736,590

(22) Filed: Jun. 7, 2024

(30) Foreign Application Priority Data
Apr. 19, 2024 (TW) 113114753

(51) Int. Cl. H01L 23/528; H01L 21/768; H01L 23/522; H01L 23/532

(52) U.S. Cl. CPC H01L 23/5283; H01L 21/76816; H01L 21/76832; H01L 21/76834; H01L 23/5226; H01L 23/53295

(57) ABSTRACT

A semiconductor interconnect structure and a method for manufacturing the same are provided. The semiconductor interconnect structure includes a first conductive element, a dielectric layer on the first conductive element, a second conductive element in the dielectric layer, a via element in the dielectric layer and extending from the first conductive element to the second conductive element, and a third conductive element in the dielectric layer. A lower surface of the third conductive element is higher than a lower surface of the second conductive element.

This application claims the benefit of Taiwan application Serial No. 113114753, filed Apr. 19, 2024, the subject matter of which is incorporated herein by reference.

### BACKGROUND

### Technical Field

The disclosure relates to a semiconductor structure and a method for manufacturing the same, and more particularly to a semiconductor interconnect structure and a method for manufacturing the same.

### Description of the Related Art

With the advancement of semiconductor technology, dimensions and feature sizes of semiconductor structures are scaled down. The reduction in size of semiconductor structures brings many new challenges. For example, the reduction in size of the semiconductor interconnect structure reduces the thickness of the dielectric layer in the semiconductor interconnect structure, which may cause dielectric breakdown (electrical breakdown) problems to occur more easily, thereby reducing the reliability of the semiconductor interconnect structure.

### SUMMARY

According to some embodiments of the present disclosure, a semiconductor interconnect structure is provided. The semiconductor interconnect structure includes a first conductive element, a dielectric layer on the first conductive element, a second conductive element in the dielectric layer, a via element in the dielectric layer and extending from the first conductive element to the second conductive element, and a third conductive element in the dielectric layer. A lower surface of the third conductive element is higher than a lower surface of the second conductive element.

According to some embodiments of the present disclosure, a semiconductor interconnect structure is provided. The semiconductor interconnect structure includes a first conductive element, a second conductive, a via element, a third conductive element, a fourth conductive element and a dielectric material. The second conductive is disposed on the first conductive element along a first direction. The via element extends from the first conductive element to the second conductive element. The first conductive element is electrically connected to the second conductive element through the via element. The third conductive element and the second conductive element are disposed along a second direction perpendicular to the first direction. The fourth conductive element and the first conductive element are disposed along the second direction. The third conductive element is electrically isolated from the fourth conductive element. The dielectric material is between the first conductive element and the second conductive element and between the third conductive element and the fourth conductive element. The dielectric material has a varied height along the first direction.

According to some embodiments of the present disclosure, a method for manufacturing a semiconductor interconnect structure is provided. The method includes: forming a first conductive element and a dielectric layer on the first conductive element; forming a first opening in the dielectric layer; forming a via opening exposing the first conductive element; forming a second opening in the dielectric layer, wherein the second opening is connected to the via opening, a bottom of the first opening is higher than a bottom of the second opening; forming a second conductive element, a via element and a third conductive element in the second opening, the via opening and the first opening respectively.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic cross-sectional view of a semiconductor interconnect structure according to some embodiments of the present disclosure.

FIGS. 2 to 12 illustrate schematic cross-sectional views of various stages in a method for manufacturing a semiconductor interconnect structure according to some embodiments of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation. In the following methods for manufacturing semiconductor devices, there may be one or more additional operations between the operations described, and the order of the operations may vary. The illustration uses the same/similar reference numerals to indicate the same/similar elements.

The following definitions and abbreviations are to be used for the interpretation of the claims and the specification. As used herein, the terms “comprises” “comprising” “includes” “including” “has” “having” “contains” or “containing” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The term “connection” can include both an indirect “connection” and a direct “connection.”

As used in the specification and the appended claims, the ordinals such as “first”, “second” and the like to describe elements do not imply or represent a specific position in the structure, or the order of arrangement, or the order of manufacturing. The ordinals are only used to clearly distinguish multiple elements with the same name. As used in the specification and the appended claims, spatial relation terms such as “on”, “above”, “over”, “upper,” “top”, “below”, “beneath”, “under”, “lower”, “bottom” and the like may be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise.

Additionally, the term “electrically connected” used in the specification and claims can refer to an ohmic contact between elements, or current passing through elements, or an operational relation between elements. The operational relation may mean, for example, that one element is used to drive another element, but current may not flow directly between these two elements. As used in the specification and the appended claims, term “deposition” includes, but is not limited to, chemical vapor deposition (CVD), physical vapor deposition (PVD), atomic layer deposition (ALD) and epitaxial growth. Depending on the type of material to be formed, a person of ordinary skill in the art can select an appropriate technology for forming the material.

As used in the specification and the appended claims, term “etching” includes, but is not limited to, dry etching and wet etching. As used in the specification and the appended claims, term “polishing process” includes, but is not limited to, a chemical-mechanical planarization (CMP) and an ion milling process. The terms “etching”, “etching back” and “polishing process” used in the specification and the appended claims may replace with each other, and a person of ordinary skill in the art can select an appropriate removal technology depending on the structure and material.

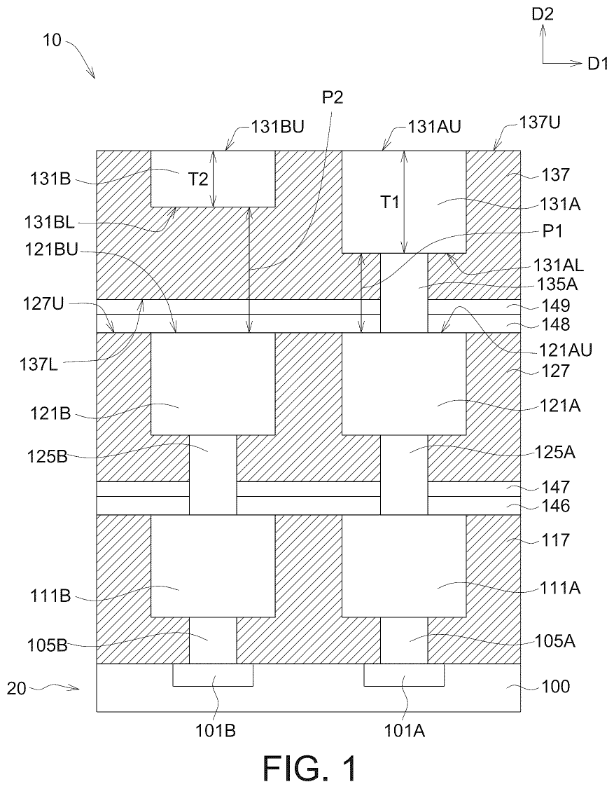

Referring to FIG. 1, FIG. 1 illustrates a schematic cross-sectional view of a semiconductor interconnect structure 10 according to some embodiments of the present disclosure. The semiconductor interconnect structure 10 includes a conductive element 121A, a conductive element 131A, a conductive element 131B, a via element 135A, and a dielectric layer 137 on the conductive element 121A. The conductive element 131A and the conductive element 131B are in the dielectric layer 137. The conductive element 131A and the conductive element 131B can be disposed along a first direction D1. The conductive element 131A may be electrically isolated from or electrically connected to the conductive element 131B. The conductive element 131A is disposed on the conductive element 121A along a second direction D2. The via element 135A can extend from the conductive element 121A to the conductive element 131A. At least a portion of the via element 135A is in the dielectric layer 137. The conductive element 131A is electrically connected to the conductive element 121A through the via element 135A. An upper surface 137U of the dielectric layer 137, an upper surface 131AU of the conductive element 131A and an upper surface 131BU of the conductive element 131B can be coplanar. In the second direction D2, a lower surface 131BL of the conductive element 131B can be higher than a lower surface 131AL of the conductive element 131A. A height T2 of the conductive element 131B in the second direction D2 is smaller than a height T1 of the conductive element 131A in the second direction D2. The first direction D1 is perpendicular to the second direction D2. The first direction D1 can be parallel to the upper surface 137U of the dielectric layer 137. The second direction D2 can be parallel to the normal direction to the upper surface 137U of the dielectric layer 137.

The semiconductor interconnect structure 10 can further include a dielectric layer 127 below the dielectric layer 137, and a conductive element 121B. The conductive elements 121A and 121B are in the dielectric layer 127. The conductive elements 121A and 121B can be disposed along the first direction D1. The conductive element 121A may be electrically isolated from or electrically connected to the conductive element 121B. The conductive element 131B is disposed on the conductive element 121B along the second direction D2. In the second direction D2, the conductive element 131B is at least partially aligned with the conductive element 121B. The term “at least partially aligned with” means at least partially overlapping in the second direction D2. The conductive element 131B is electrically isolated from the conductive element 121B. There may be an electrical potential difference between the conductive element 121B and the conductive element 131B.

In some embodiments, the semiconductor interconnect structure 10 further includes an etch stop layer 148 and an etch stop layer 149 between the conductive element 121A and the dielectric layer 137. The etch stop layers 148 and 149 include different materials. The via element 135A may extend along the second direction D2 and pass through the dielectric layer 137, the etch stop layer 148 and the etch stop layer 149. The etch stop layer 148 is between the etch stop layer 149 and the dielectric layer 127. The etch stop layer 148 may contact an upper surface 127U of the dielectric layer 127, an upper surface 121AU of the conductive element 121A and an upper surface 121BU of the conductive element 121B. The etch stop layer 149 is between the etch stop layer 148 and the dielectric layer 137. The etch stop layer 149 may contact a lower surface 137L of the dielectric layer 137.

In some embodiments, the semiconductor interconnect structure 10 includes any one of the etch stop layer 148 and the etch stop layer 149, or includes one or more other etch stop layers on the etch stop layer 148, or on the etch stop layer 149, or between the etch stop layers 148 and 149.

The semiconductor interconnect structure 10 can further include a dielectric layer 117, a contact element 105A, a contact element 105B, a conductive element 111A, a conductive element 111B, a via element 125A, a via element 125B, an etch stop layer 146 and an etch stop layer 147. The dielectric layer 117 is below the dielectric layer 127. The etch stop layer 146 is between the dielectric layer 117 and the etch stop layer 147. The etch stop layer 147 is between the etch stop layer 146 and the dielectric layer 127. The via elements 125A and 125B can be disposed along the first direction D1 and separated from each other. The via element 125A can extend from the conductive element 121A to the conductive element 111A along the second direction D2 and pass through the dielectric layer 127, the etch stop layer 147 and the etch stop layer 146. The via element 125B can extend from the conductive element 121B to the conductive element 111B along the second direction D2 and pass through the dielectric layer 127, the etch stop layer 147 and the etch stop layer 146. The contact elements 105A and 105B can be disposed along the first direction D1 and separated from each other. The contact elements 105A and 105B are in the dielectric layer 117. The conductive elements 111A and 111B can be disposed along the first direction D1. The conductive element 111A may be electrically isolated from or electrically connected to the conductive element 111B. The conductive elements 111A and 111B are in the dielectric layer 117. The conductive element 111A is between the via element 125A and the contact element 105A. The conductive element 111B is between the via element 125B and the contact element 105B.

The semiconductor interconnect structure 10 may be disposed on a semiconductor structure 20 including a semiconductor element 101A and a semiconductor element 101B to realize signal transmission of the semiconductor elements 101A and 101B. The semiconductor structure 20 may include a substrate 100, the semiconductor element 101A and the semiconductor element 101B. The semiconductor elements 101A and 101B can be formed in the substrate 100 or on the substrate 100. The semiconductor element 101A can be separated from the semiconductor element 101B. The semiconductor elements 101A and 101B can be any electronic components such as transistors, resistors or inductors. The dielectric layer 117 can be disposed on the substrate 100. The contact element 105A can extend from the conductive element 111A to the semiconductor element 101A. The contact element 105B can extend from the conductive element 111B to the semiconductor element 101B. The semiconductor element 101A is electrically connected to the contact element 105A, the conductive element 111A, the via element 125A, the conductive element 121A, the via element 135A and the conductive element 131A to form functional circuits. The semiconductor element 101B is electrically connected to the contact element 105B, the conductive element 111B, the via element 125B and the conductive element 121B to form functional circuits. The semiconductor interconnect structure 10 and the semiconductor structure 20 may be part of an integrated circuit chip.

In the embodiment shown in FIG. 1, the conductive elements 111A and 111B can be defined as the first metallization layer (M1), the conductive elements 121A and 121B can be defined as the second metallization layer (M2), the conductive elements 131A and 131B can be defined as the third metallization layer (M3), but the present disclosure is not limited thereto. A distance P2 between the lower surface 131BL of the conductive element 131B and the upper surface 121BU of the conductive element 121B along the second direction D2 is greater than a distance P1 between the lower surface 131AL of the conductive element 131A and the upper surface 121AU of the conductive element 121A along the second direction D2. The distance P2 can be defined as a thickness of the dielectric material between two adjacent conductive elements disposed along the second direction, and the dielectric material includes the etch stop layer 148, the etch stop layer 149 and the dielectric layer 137. The distance P1 can be defined as a thickness of the dielectric material between two adjacent conductive elements disposed along the second direction, and the dielectric material includes the etch stop layer 148, the etch stop layer 149 and the dielectric layer 137. In the present embodiment, the distance P2 is not equal to the distance P1, that is, the dielectric material between two metallization layers (such as the second metallization layer (M2) and the third metallization layer (M3)) has a varied height along the second direction D2.

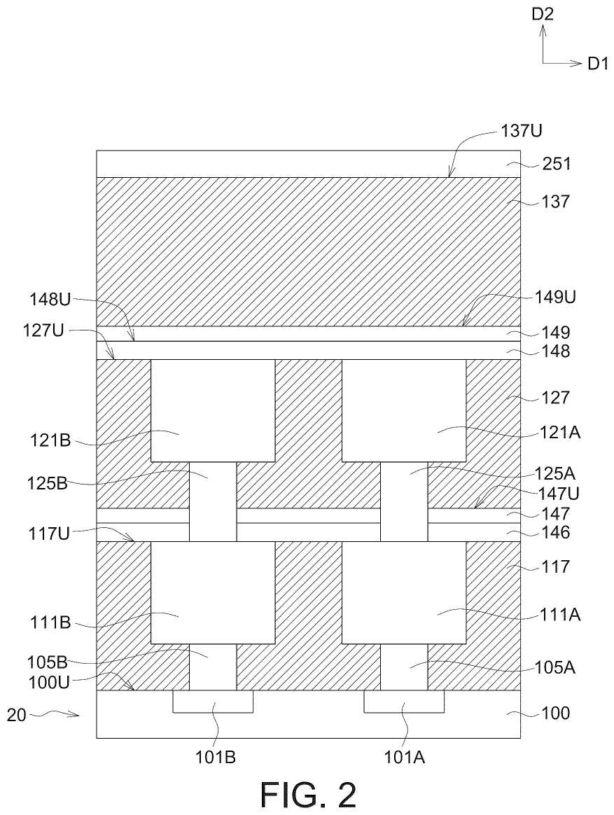

FIGS. 2 to 12 illustrate schematic cross-sectional views of various stages in a method for manufacturing a semiconductor interconnect structure according to some embodiments of the present disclosure.

Referring to FIG. 2, FIG. 2 shows a schematic cross-sectional view of the structure at one stage of the manufacturing method. A semiconductor structure 20 is provided. The semiconductor structure 20 includes a substrate 100, a semiconductor element 101A in the substrate 100 or on the substrate 100, and a semiconductor element 101B in the substrate 100 or on the substrate 100. The substrate 100 can be a semiconductor substrate, such as bulk semiconductor substrate or SOI (silicon-on-insulator) substrate. The substrate 100 can be a wafer, such as silicon wafer. The semiconductor materials of the substrate 100 can be silicon, germanium, silicon carbide, gallium arsenide, gallium phosphide, indium arsenide, indium phosphide, indium antimonide, or any combinations thereof. The semiconductor elements 101A and 101B can be formed in the active region of the substrate 100. The semiconductor elements 101A and 101B may be completely formed within the substrate 100, or may be completely formed on the upper surface 100U of the substrate 100, or may be partially formed within the substrate 100 and partially on the upper surface 100U of the substrate 100. The semiconductor elements 101A and 101B can be formed by any suitable method.

A dielectric layer 117 is formed on the upper surface 100U of the substrate 100. Contact elements 105A and 105B are formed in the dielectric layer 117. Conductive elements 111A and 111B are formed in the dielectric layer 117. The dielectric layer 117 may be formed through a deposition process. The contact element 105A, the contact element 105B, the conductive element 111A and the conductive element 111B may be formed through photolithography processes, etching processes and deposition processes.

Etch stop layers 146 and 147 are sequentially formed on an upper surface 117U of the dielectric layer 117. A dielectric layer 127 is formed on an upper surface 147U of the etch stop layer 147. Via elements 125A and 125B are formed in the dielectric layer 127. Conductive elements 121A and 121B are formed in the dielectric layer 127. The etch stop layer 146, the etch stop layer 147 and the dielectric layer 127 may be formed through deposition processes. The via element 125A, the via element 125B, the conductive element 121A and the conductive element 121B may be formed through photolithography processes, etching processes and deposition processes.

An Etch stop layer 148 is formed on an upper surface 127U of the dielectric layer 127. An Etch stop layer 149 is formed on an upper surface 148U of the dielectric layer 148. A dielectric layer 177 is formed on an upper surface 149U of the etch stop layer 149. A mask layer 251 is formed on the upper surface 137U of the dielectric layer 137. The etch stop layer 148, the etch stop layer 149, the dielectric layer 137 and the mask layer 251 may be formed through deposition processes. The dielectric layer 137 is above the conductive elements 121A and 121B.

The dielectric layers 117, 127 and 137 may include dielectric materials such as low dielectric constant (low-k) dielectric materials or ultra low-k dielectric materials. Low-k dielectric materials are materials having a dielectric constant smaller than the dielectric constant of silicon dioxide (approximately 3.9) such as carbon-doped oxide. Ultra low-k dielectric materials are materials having a dielectric constant smaller than 2.5 such as porous carbon-doped oxide. The materials of the dielectric layers 117, 127 and 137 may be the same or different. The contact element 105A, the contact element 105B, the via element 125A, the via element 125B, the conductive element 111A, the conductive element 111B, the conductive element 121A and the conductive element 121B may include conductive materials such as copper, tungsten, gold, cobalt or any combinations thereof. The materials of the contact element 105A, the contact element 105B, the via element 125A, the via element 125B, the conductive element 111A, the conductive element 111B, the conductive element 121A and the conductive element 121B may be the same or different. The etch stop layers 146 and 147 include different materials. The etch stop layer 146 includes nitride such as silicon nitride. The etch stop layer 147 includes oxide such as silicon oxide. The etch stop layers 148 and 149 include different materials. The etch stop layer 148 includes nitride such as silicon nitride. The etch stop layer 149 includes oxide such as silicon oxide. The mask layer 251 may include metal compound a metal compound such as titanium nitride.

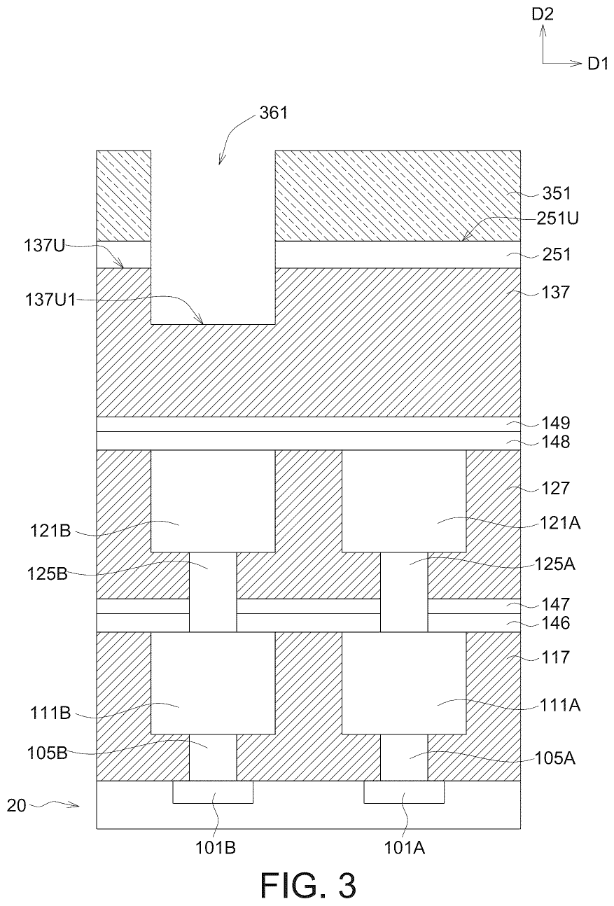

Referring to FIG. 3, FIG. 3 shows a schematic cross-sectional view of the structure at one stage of the manufacturing method. A photoresist layer 351 is formed on the dielectric layer 137 and the mask layer 251. An opening 361 is formed in the photoresist layer 351, the mask layer 251 and the dielectric layer 137. The photoresist layer 351 may cover an upper surface 251U of the mask layer 251. The opening 361 may extend along the second direction D2 and pass through the photoresist layer 351, the mask layer 251 and the dielectric layer 137. The bottom of the opening 361 can be in the dielectric layer 137. The opening 361 exposes a sidewall of the photoresist layer 351, a sidewall of the mask layer 251, a sidewall of the dielectric layer 137 and an upper surface 137U1 of the dielectric layer 137. The upper surface 137U1 of the dielectric layer 137 is lower than the upper surface 137U of the dielectric layer 137 in the second direction D2. The photoresist layer 351 may include any suitable photoresist such as KrF photoresist, ArF photoresist or EUV (extreme ultraviolet) photoresist. The photoresist layer 351 may be formed through a deposition process. The opening 361 may be formed through a photolithography process and an etching process.

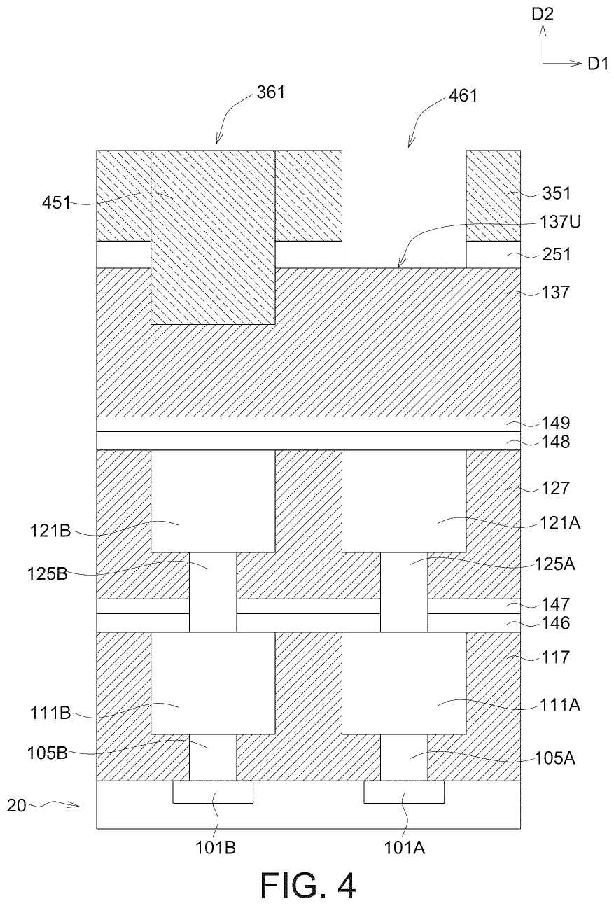

Referring to FIG. 4, FIG. 4 shows a schematic cross-sectional view of the structure at one stage of the manufacturing method. The opening 361 is filled with a photoresist material 451. An opening 461 is formed in the photoresist layer 351 and the mask layer 251. The opening 461 may extend along the second direction D2 and pass through the photoresist layer 351 and the mask layer 251. The opening 461 exposes a sidewall of the photoresist layer 351, a sidewall of the mask layer 251 and the upper surface 137U of the dielectric layer 137. The opening 461 is separated from the opening 361. The photoresist material 451 may include any suitable photoresist such as KrF photoresist, ArF photoresist or EUV photoresist. The photoresist material 451 and the photoresist layer 351 may include the same material. The photoresist material 451 may be formed in the opening 361 through a deposition process. The opening 461 may be formed through a photolithography process and an etching process.

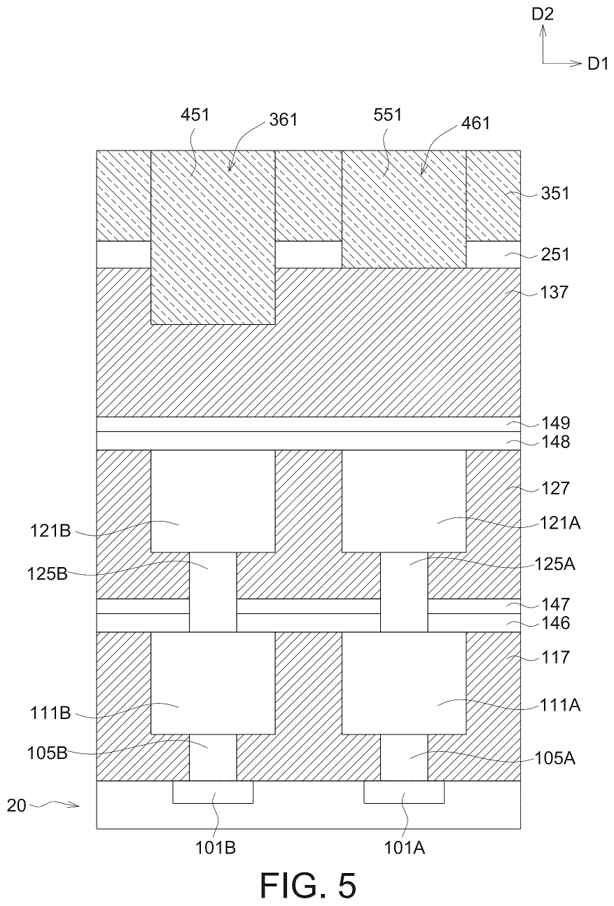

Referring to FIG. 5, FIG. 5 shows a schematic cross-sectional view of the structure at one stage of the manufacturing method. The opening 461 is filled with a photoresist material 551. The photoresist material 551 may include any suitable photoresist such as KrF photoresist, ArF photoresist or EUV photoresist. The photoresist material 551 and the photoresist layer 351 may include the same material. The photoresist material 551 may be formed in the opening 461 through a deposition process.

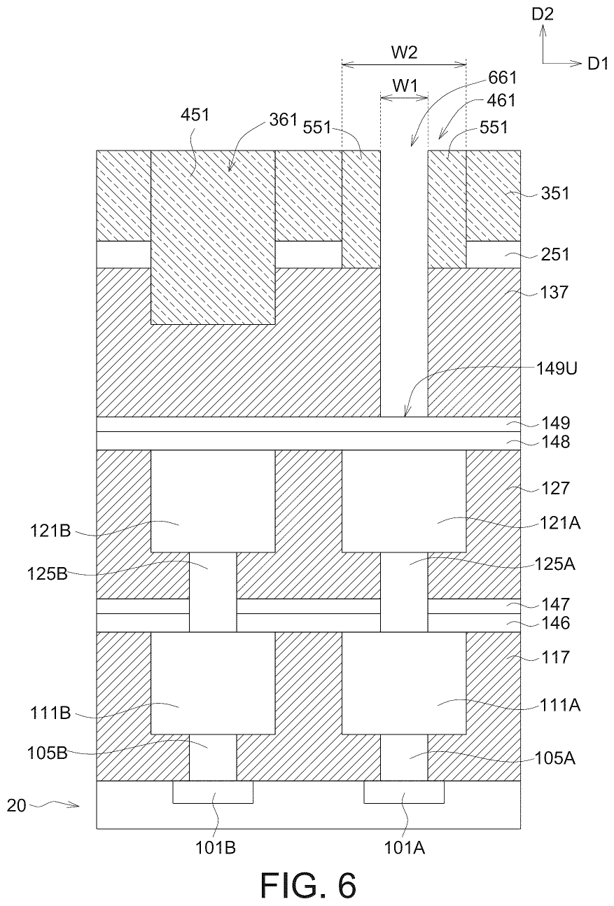

Referring to FIG. 6, FIG. 6 shows a schematic cross-sectional view of the structure at one stage of the manufacturing method. A trench 661 passing through the photoresist material 551 and the dielectric layer 137 is formed. The trench 661 may extend along the second direction D2. The trench 661 exposes a sidewall of the photoresist material 551, a sidewall of the dielectric layer 137 and the upper surface 149U of the etch stop layer 149. A width W1 of the trench 661 in the first direction D1 is smaller than a width W2 of the opening 461 in the first direction D1. The trench 661 may be formed through a photolithography process and an etching process.

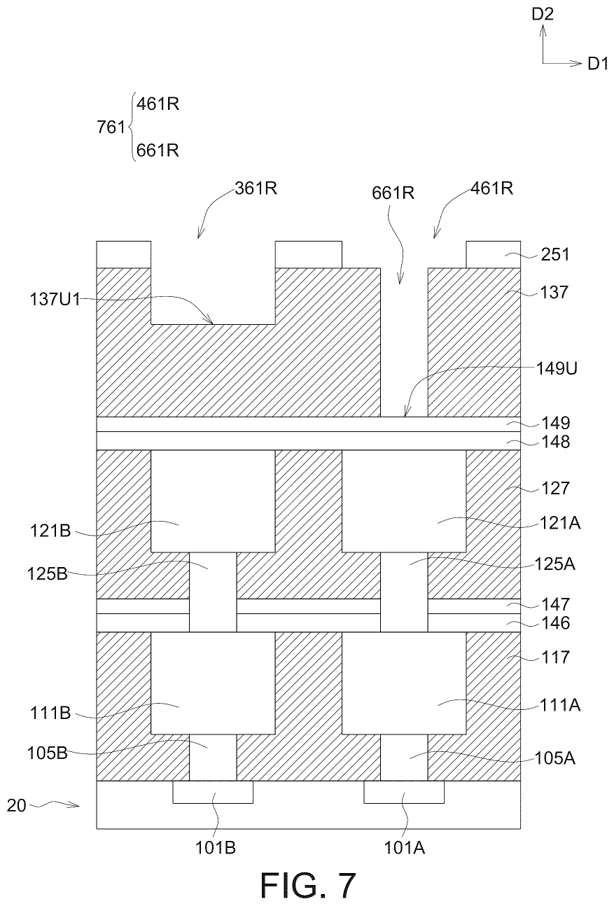

Referring to FIG. 7, FIG. 7 shows a schematic cross-sectional view of the structure at one stage of the manufacturing method. The photoresist layer 351, the photoresist material 451 and the photoresist material 551 are removed to expose the mask layer 251. After removing the photoresist layer 351, the photoresist material 451 and the photoresist material 551, the structure (as shown in FIG. 7) includes an opening 361R and an opening 761 separated from each other. The opening 361R extends along the second direction D2 and pass through the mask layer 251 and the dielectric layer 137. The opening 361R can be a lower portion of the opening 361 shown in FIGS. 3 to 6. The opening 361R exposes a sidewall of the mask layer 251, a sidewall of the dielectric layer 137 and the upper surface 137U1 of the dielectric layer 137. The opening 761 includes an opening 461R and a trench 661R that are connected to (or communicate with) each other. The opening 461R is above the trench 661R. The opening 461R passes through the mask layer 251. The trench 661R passes through the dielectric layer 137. The opening 461R can be a lower portion of the opening 461 shown in FIGS. 4 to 6. The trench 661R can be a lower portion of the trench 661 shown in FIG. 6. The opening 761 exposes a sidewall of the mask layer 251, a sidewall of the dielectric layer 137 and the upper surface 149U of the etch stop layer 147. The photoresist layer 351, the photoresist material 451 and the photoresist material 551 may be removed through an etching process and thus the structure shown in FIG. 7 is formed.

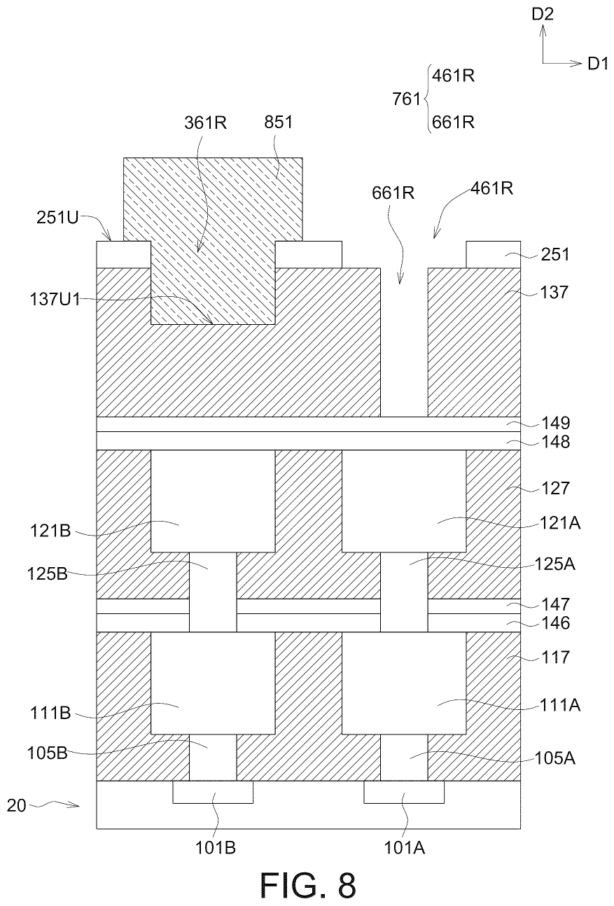

Referring to FIG. 8, FIG. 8 shows a schematic cross-sectional view of the structure at one stage of the manufacturing method. A protection layer 851 is formed in the opening 361R. The protection layer 851 does not fill the opening 461R and the trench 661R. The protection layer 851 fills the opening 361R and covers a portion of the upper surface 251U of the mask layer 251. The protection layer 851 may include any suitable photoresist such as KrF photoresist, ArF photoresist or EUV photoresist. The protection layer 851 may be formed through a deposition process.

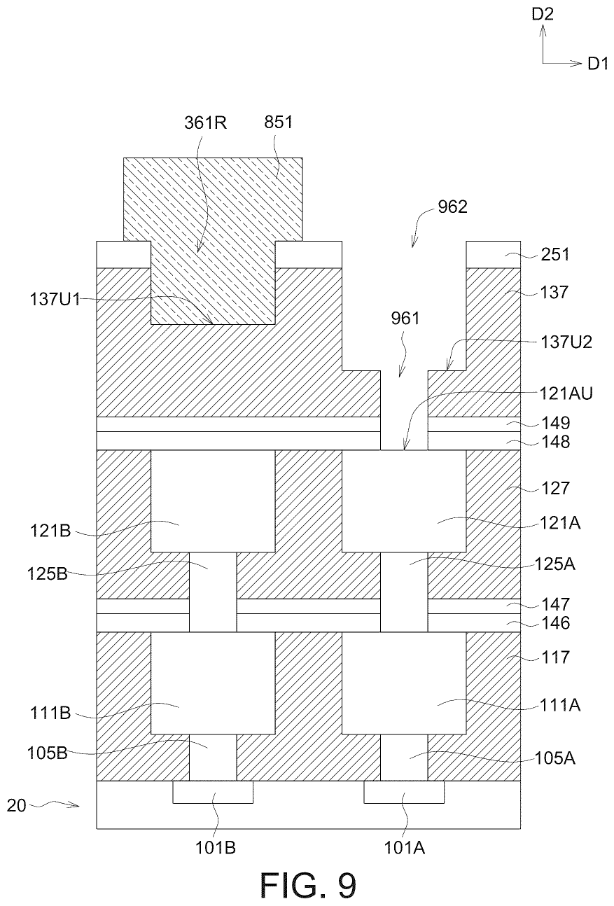

Referring to FIG. 9, FIG. 9 shows a schematic cross-sectional view of the structure at one stage of the manufacturing method. A via opening 961 and an opening 962 above the via opening 961 are formed. The via opening 961 is connected to (or communicate with) the opening 962. The opening 962 extends along the second direction D2 and passes through the mask layer 251 and the dielectric layer 137. The opening 962 exposes a sidewall of the mask layer 251, a sidewall of the dielectric layer 137 and an intermediate surface 137U2 of the dielectric layer 137. The bottom of the opening 962 is in the dielectric layer 137. The via opening 961 extends along the second direction D2 and passes through the dielectric layer 137, the etch stop layer 149 and the etch stop layer 148. The via opening 961 exposes a sidewall of the dielectric layer 137, a sidewall of the etch stop layer 149, a sidewall of the etch stop layer 148 and an upper surface 121AU of the conductive element 121A. The bottom of the opening 361R (i.e. the upper surface 137U1 of the dielectric layer 137) is higher than the bottom of the opening 962 (i.e. the intermediate surface 137U2 of the dielectric layer 137) in the second direction D2. An etching process can be performed to the opening 461R and the trench 661R shown in FIG. 8 to form the via opening 961 an the opening 962. The amount of the etch stop layers 148 and 149 that is removed is less than the amount of the dielectric layer 137 that is removed during the etching process because the etch rate of the etch stop layers 148 and 149 is lower than the etch rate of the dielectric layer 137. As such, the profiles of the via opening 961 and the opening 962 as shown in FIG. 9 can be formed. During the etching process, the protection layer 851 is retained without being removed.

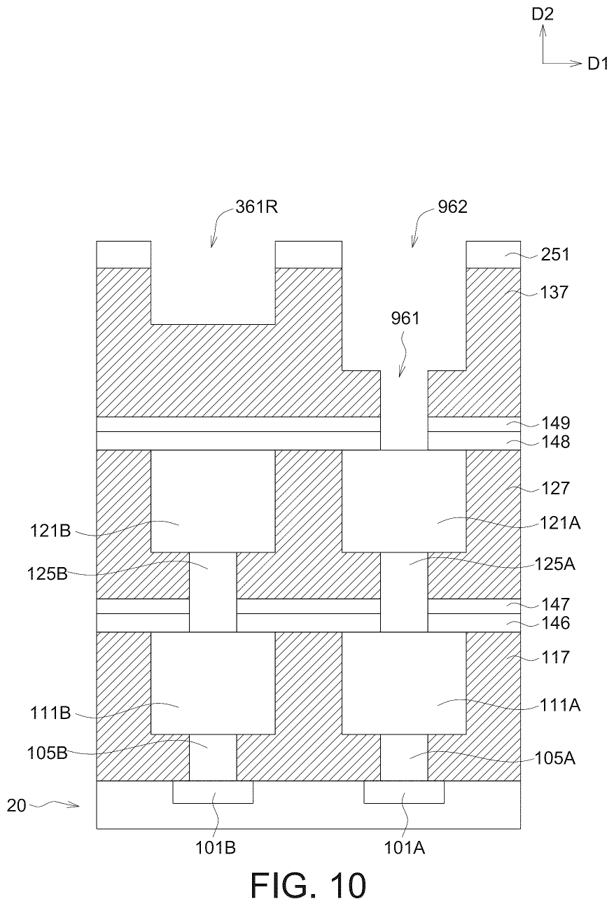

Referring to FIG. 10, FIG. 10 shows a schematic cross-sectional view of the structure at one stage of the manufacturing method. The protection layer 851 is removed to expose the opening 361R. The protection layer 851 may be removed through an etching process.

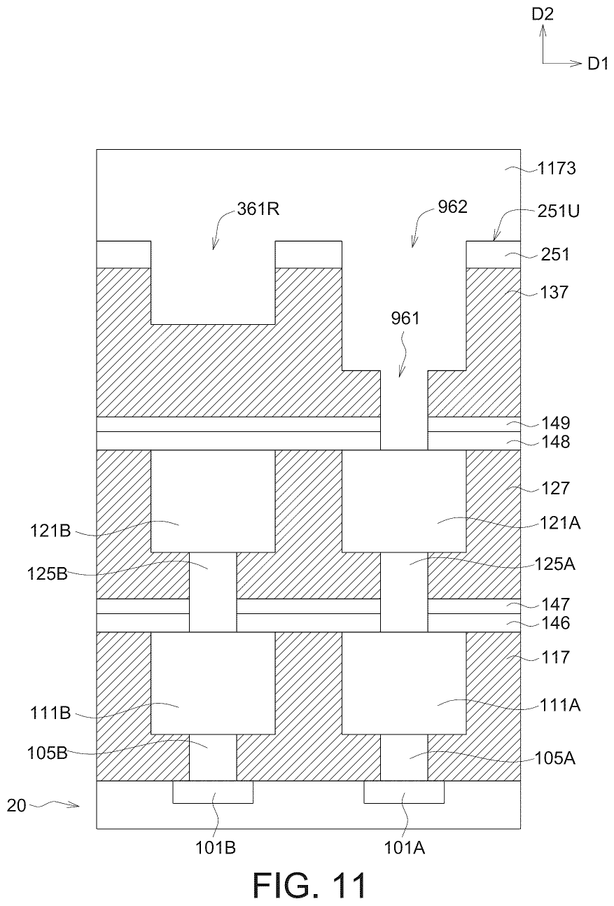

Referring to FIG. 11, FIG. 11 shows a schematic cross-sectional view of the structure at one stage of the manufacturing method. The opening 361R, the via opening 961 and the opening 962 are filled with a conductive material 1173. The conductive material 1173 may cover the upper surface 251U of the mask layer 251. The conductive material 1173 may contact the conductive element 121A, the etch stop layer 148, the etch stop layer 149, the dielectric layer 137 and the mask layer 251. The conductive material 1173 can be copper, tungsten, gold, cobalt or any combination thereof. The conductive material 1173 may be formed in the opening 361R, in the via opening 961, in the opening 962, and on the upper surface 251U of the mask layer 251.

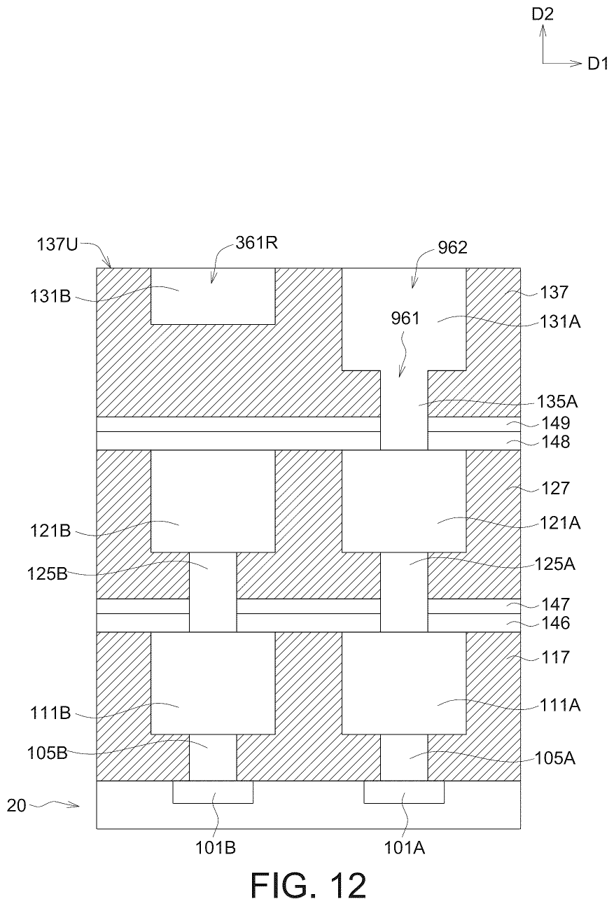

Referring to FIG. 12, FIG. 12 shows a schematic cross-sectional view of the structure at one stage of the manufacturing method. A conductive element 131A, a via element 135A and a conductive element 131B are formed in the opening 962, the via opening 961 and the opening 361R respectively. A portion of the conductive material 1173 above the upper surface 137U of the dielectric layer 137, and the mask layer 251 may be removed through an etching process or a polishing process; portion of the conductive material 1173 below the upper surface 137U of the dielectric layer 137 is retained. A portion of the retained portion of the conductive material 1173 in the opening 962 can be defined as the conductive element 131A, a portion of the retained portion of the conductive material 1173 in the via opening 961 can be defined as the via element 135A, and a portion of the retained portion of the conductive material 1173 in the opening 361R can be defined as the conductive element 131B. The conductive element 131B is at least partially aligned with the conductive element 121B.

In an embodiment, through the method schematically illustrated in FIGS. 2 to 12, a semiconductor interconnect structure 10 shown in FIG. 1 is provided.

In the semiconductor interconnect structure according to the present disclosure, the lower surface of the conductive element 131B is higher than the lower surface of the conductive element 131A, which means that the thickness of the dielectric material (including the etch stop layer 148, the etch stop layer 149 and the dielectric layer 137) between the conductive element 131B and the conductive element 121B is greater than the thickness of the dielectric material (including the etch stop layer 148, the etch stop layer 149 and the dielectric layer 137) between the conductive element 131A and the conductive element 121A. When there is an electrical potential difference between the conductive element 121B and the conductive element 131B, the thicker dielectric material between the conductive element 131B and the conductive element 121B can improve the dielectric breakdown problem; that is, the dielectric material between the conductive element 131B and the conductive element 121B can withstand higher potential differences without dielectric breakdown (i.e. with a high breakdown voltage). As such, the reliability of the semiconductor interconnect structure can be improved. In addition, the thinner dielectric material between conductive element 131A and conductive element 121A can increase the operating speed of elements. Therefore, the semiconductor interconnect structure according to the present disclosure can achieve high reliability and high operating speed.

In a comparative example of a semiconductor interconnect structure, the dielectric material between two adjacent metallization layers has an uniform thickness. When the thickness of the dielectric material between two adjacent metallization layers is thinner, the operating speed of elements is increased, but the thinner dielectric material can easily lead to dielectric breakdown problems (i.e. with a low breakdown voltage). When the thickness of the dielectric material between two adjacent metallization layers is thicker, the dielectric breakdown problem is less likely to occur, but the operating speed of elements is slower. Therefore, it is difficult for the semiconductor interconnect structure in the comparative example to take into account the operating speed of elements and the dielectric breakdown problem at the same time, and the semiconductor interconnect structure in the comparative example cannot achieve high reliability and high operating speed.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor interconnect structure, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor interconnect structure, comprising
a first conductive element;
a dielectric layer on the first conductive element;
a second conductive element in the dielectric layer;
a via element in the dielectric layer and extending from the first conductive element to the second conductive element; and
a third conductive element in the dielectric layer,
wherein a lower surface of the third conductive element is higher than a lower surface of the second conductive element.

2. The semiconductor interconnect structure according to claim 1, wherein an upper surface of the dielectric layer, an upper surface of the second conductive element and an upper surface of the third conductive element are coplanar.

3. The semiconductor interconnect structure according to claim 1, further comprising a first etch stop layer between the first conductive element and the dielectric layer.

4. The semiconductor interconnect structure according to claim 3, further comprising a second etch stop layer between the first etch stop layer and the dielectric layer, wherein the first etch stop layer and the second etch stop layer comprise different materials.

5. The semiconductor interconnect structure according to claim 3, wherein the via element pass through the first etch stop layer.

6. The semiconductor interconnect structure according to claim 1, further comprising a fourth conductive element below the dielectric layer and separated from the first conductive element, wherein the third conductive element is at least partially aligned with the fourth conductive element.

7. The semiconductor interconnect structure according to claim 6, wherein the third conductive element is electrically isolated from the fourth conductive element.

8. The semiconductor interconnect structure according to claim 6, wherein a distance between the lower surface of the third conductive element and an upper surface of the fourth conductive element is greater than a distance between the lower surface of the second conductive element and an upper surface of the first conductive element.

9. The semiconductor interconnect structure according to claim 1, wherein a height of the third conductive element is smaller than a height of the second conductive element.

10. The semiconductor interconnect structure according to claim 9, wherein an upper surface of the dielectric layer, an upper surface of the second conductive element and an upper surface of the third conductive element are coplanar.

11. A semiconductor interconnect structure, comprising
a first conductive element;
a second conductive, disposed on the first conductive element along a first direction;
a via element extending from the first conductive element to the second conductive element, wherein the first conductive element is electrically connected to the second conductive element through the via element;
a third conductive element, wherein the third conductive element and the second conductive element are disposed along a second direction perpendicular to the first direction;
a fourth conductive element, wherein the fourth conductive element and the first conductive element are disposed along the second direction, and the third conductive element is electrically isolated from the fourth conductive element; and
a dielectric material between the first conductive element and the second conductive element and between the third conductive element and the fourth conductive element,
wherein the dielectric material has a varied height along the first direction.

12. The semiconductor interconnect structure according to claim 11, wherein a height of the dielectric material between the third conductive element and the fourth conductive element is greater than a height of the dielectric material between the first conductive element and the second conductive element.

13. A method for manufacturing a semiconductor interconnect structure, comprising:
forming a first conductive element and a dielectric layer on the first conductive element;
forming a first opening in the dielectric layer;
forming a via opening exposing the first conductive element;
forming a second opening in the dielectric layer, wherein the second opening is connected to the via opening, a bottom of the first opening is higher than a bottom of the second opening; and
forming a second conductive element, a via element and a third conductive element in the second opening, the via opening and the first opening respectively.

14. The method according to claim 13, further comprising:
forming a photoresist layer on the dielectric layer;
forming a third opening in the photoresist layer, wherein the third opening exposes an upper surface of the dielectric layer;
filling the third opening with a photoresist material; and
forming a trench passing through the photoresist material and the dielectric layer, wherein a width of the trench is smaller than a width of the third opening.

15. The method according to claim 13, further comprising:
forming a first etch stop layer on the first conductive element, and a second etch stop layer on the first etch stop layer,
wherein the first etch stop layer and the second etch stop layer comprise different materials.

16. The method according to claim 15, further comprising:
forming a photoresist layer on the dielectric layer;
forming a third opening in the photoresist layer, wherein the third opening exposes an upper surface of the dielectric layer;
filling the third opening with a photoresist material; and
forming a trench passing through the photoresist material and the dielectric layer, wherein the trench exposes the second etch stop layer.

17. The method according to claim 16, further comprising:
performing an etching process to the trench to form the via opening an the second opening above the via opening.

18. The method according to claim 13, wherein the via element extends from the first conductive element to the second conductive element.

19. The method according to claim 13, further comprising:
forming a fourth conductive element below the dielectric layer, wherein the fourth conductive element is separated from the first conductive element and the third conductive element is at least partially aligned with the fourth conductive element.

20. The method according to claim 19, wherein the third conductive element is electrically isolated from the fourth conducive element.
